(19) United States
(12) Patent Application Publication
(10) Pub. No.: US 2008/0121937 A1
(43) Pub. Date: May 29, 2008

(54) HETEROJUNCTION BIPOLAR TRANSISTOR WITH MONOCRYSTALLINE BASE AND RELATED METHODS

(75) Inventors: Thomas N Adam, Poughkeepsie, NY (US); Thomas A. Wallner, Pleasant Valley, NY (US)

Correspondence Address: HOFFMAN, WARNICK & D'ALESSANDRO LLC, 75 STATE ST, 14TH FL, ALBANY, NY, 12207, US

(73) Assignee: INTERNATIONAL BUSINESS MACHINES CORPORATION, Armonk, NY (US)

(21) Appl. No.: 11/557,680

(22) Filed: Nov. 8, 2006

(51) Int. Cl. H01L 29/737; H01L 21/331

(52) U.S. Cl. 257/197; 438/318; 257/E29.188; 257/E21.371

(57) ABSTRACT

A heterostructure bipolar transistor (HBT) and related methods are disclosed. In one embodiment, the HBT includes a substrate; a polysilicon emitter atop the substrate; a collector in the substrate; at least one isolation region adjacent to the collector; an intrinsic base including monocrystalline silicon germanium extending over each isolation region; and a monocrystalline extrinsic base. One method includes replacing isolation region formation with formation of porous implanted silicon, which is later converted to a dielectric. As a result, a monocrystalline silicon germanium profile base layer may be formed with extended lateral dimensions over the isolation region(s).

### BACKGROUND OF THE INVENTION

1. Technical Field

The invention relates generally to integrated circuit (IC) chip fabrication, and more particularly, to a heterostructure bipolar transistor (HBT) with a monocrystalline base and methods related thereto.

2. Background Art

Heterostructure bipolar transistors (HBT) are high performance transistor structures used widely in integrated circuit (IC) chips. Referring to FIG. 1, an HBT 10 uses different types of semiconductor materials and includes three basic components: a base 12 (including an intrinsic base 14 and an extrinsic base 16), a collector (active area) 18 and an emitter 20. HBT 10 relies on a non-selective deposition of a p-type silicon germanium (SiGe) base 12 layer over collector 18 and deep-trench 24 and/or shallow-trench 26 isolation regions. In particular, intrinsic base 14 of HBT 10 is epitaxially grown at very-low temperatures (550° C. and below) onto active area 18 bound by deep-trench 24 and/or shallow-trench 26 isolation regions. As a consequence, intrinsic base 14 is monocrystalline silicon, while the part of the deposition over isolation regions 24, 26, which include silicon oxide (SiO₂), grows as polycrystalline or amorphous silicon materials. Low-temperature non-selective deposition of doped and undoped silicon (Si) and silicon germanium (SiGe) is faceted and with different growth rates for monocrystalline and polycrystalline layers. Hence, layer 12 is thicker over collector 18 and thinner over deep-trench 24 and/or shallow-trench 26 isolation regions. In addition to this non-conformality of deposition, the addition of germanium (Ge) may yield silicon germanium (SiGe) cluster/huts/pyramids in the polycrystalline portion over isolation regions 24, 26, even though monocrystalline intrinsic base 14 is substantially two-dimensional.

As a result, polycrystalline intrinsic base 14 is thinner (by approximately 20-30%) and, more importantly, the dopant containing silicon germanium (SiGe) over deep-trench 24 and/or shallow-trench 26 isolation regions may be discontinuous, which prevents adequate formation of extrinsic base 16 thereover. This structure results in increased link resistance (R_{b}) between the polysilicon of extrinsic base 16 and intrinsic base 14. In addition, the structure increases sheet resistance of the polysilicon germanium of base 12 over the silicon oxide of isolation regions 24, 26. In addition, this structure creates increased collector 18 to base 12 capacitance (C_{cb}). Current methods of forming the above-described structure also do not allow for self-alignment.

### SUMMARY OF THE INVENTION

A heterostructure bipolar transistor (HBT) and related methods are disclosed. In one embodiment, the HBT includes a substrate; a polysilicon emitter atop the substrate; a collector in the substrate; at least one isolation region adjacent to the collector; an intrinsic base including monocrystalline silicon germanium extending over each isolation region; and a monocrystalline extrinsic base. One method includes replacing isolation region formation with formation of porous implanted silicon, which is later converted to a dielectric. As a result, a monocrystalline silicon germanium profile base layer may be formed with extended lateral dimensions over the isolation region(s).

A first aspect of the invention provides a method of forming a heterostructure bipolar transistor (HBT), the method comprising: providing a substrate; forming an implanted region in the substrate; forming a monocrystalline silicon germanium base profile layer over the implanted region and the substrate; forming a dummy emitter on the monocrystalline silicon germanium base profile layer; epitaxial growing a monocrystalline extrinsic base over the monocrystalline silicon germanium base profile layer; converting the implanted region to an isolation region; and replacing the dummy emitter with a polysilicon emitter.

A second aspect of the invention provides a heterostructure bipolar transistor (HBT) comprising: a substrate; a polysilicon emitter atop the substrate; a collector in the substrate; at least one isolation region adjacent to the collector; an intrinsic base including monocrystalline silicon germanium extending over each isolation region; and a monocrystalline extrinsic base.

A third aspect of the invention provides a method comprising: providing a substrate; forming an implanted region in the substrate; forming a monocrystalline silicon germanium layer over the implanted region and the substrate; forming other structure over the monocrystalline silicon germanium layer; and converting the implanted region to an isolation region.

The illustrative aspects of the present invention are designed to solve the problems herein described and/or other problems not discussed.

### BRIEF DESCRIPTION OF THE DRAWINGS

These and other features of this invention will be more readily understood from the following detailed description of the various aspects of the invention taken in conjunction with the accompanying drawings that depict various embodiments of the invention, in which:

FIG. 1 shows a conventional heterostructure bipolar transistor (HBT).

FIGS. 2-11 show a first embodiment of a method of forming an HBT, with FIG. 11 showing one embodiment of an HBT.

FIGS. 12-13 show an alternative embodiment of a method.

FIG. 14 shows another alternative embodiment of a method.

FIGS. 15-20 show a second embodiment of a method of forming an HBT, with FIG. 19 showing one embodiment of an HBT.

FIG. 21 shows an alternative embodiment of a method.

FIG. 22 shows an alternative embodiment of a method.

FIG. 23 shows another alternative embodiment of a method.

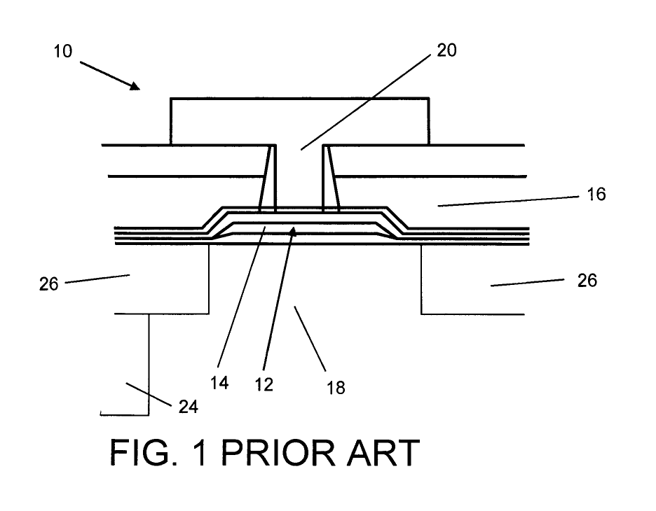

It is noted that the drawings of the invention are not to scale. The drawings are intended to depict only typical aspects of the invention, and therefore should not be considered as limiting the scope of the invention. In the drawings, like numbering represents like elements between the drawings.

### DETAILED DESCRIPTION

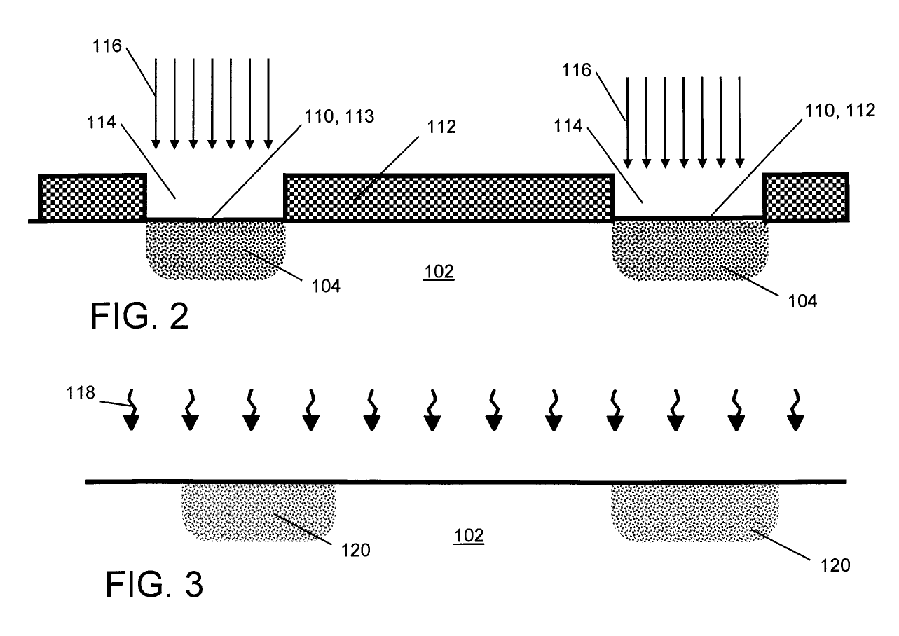

Turning to the drawings, FIGS. 2-23 show various embodiments of a method, and in particular, a method of forming a heterostructure bipolar transistor (HBT) 100, 200 (FIGS. 11, 13, 14 and 20-22).

FIGS. 2-11 show a first embodiment of a method. FIG. 2 shows providing a substrate 102. Substrate 102 may include but is not limited to: silicon and silicon germanium. In any case, substrate 102 is monocrystalline. FIG. 2 also shows one embodiment of forming an implanted region 104 (two shown) in substrate 102, which will ultimately become isolation region 106 (FIG. 11), as described herein. Implanted region 104 includes an upper surface 110 capable of having monocrystalline silicon formed thereon. In this case, implanted region 104 includes the monocrystalline silicon (now doped) of substrate 102. Implanted region 104 may be formed, for example, by forming a mask 112 and patterning/etching to form an opening 114 therein, and then ion implanting 116. The dopant implanted may include any p-type silicon dopant, for example, boron (B). In this embodiment, upper surface 110 of implanted region 104 is substantially co-planar with a surface 113 of substrate 102, i.e., ion implanting 116 uses sufficient power to provide a shallow implant to form upper surface 110.

FIG. 3 shows removing mask 112 (FIG. 2) and performing an anodic porousification 118 on implanted region 104 (FIG. 2) to form implanted porous silicon regions 120. The mask removal may include any conventional resist stripping technique, e.g., wet etching. Anodic porousification 118 may include performing a hydrofluoric acid bath using a current density of approximately 20-100 mA/cm². Porousification may be performed in darkness, or under exposure to light.

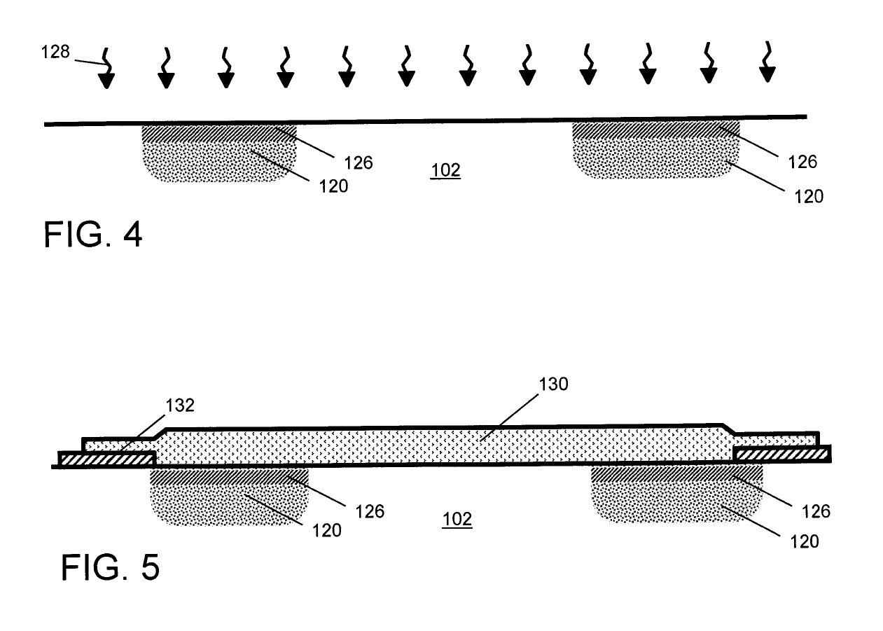

Next, as shown in FIG. 4, upper surface 110 (FIG. 2) is formed into a monocrystalline silicon film 126 by annealing 128, e.g., at a high temperature in the range of 800-1100° C. under flow of hydrogen.

FIG. 5 shows forming a monocrystalline silicon germanium (SiGe) base profile layer 130 over implanted porous silicon region 120 and substrate 102. This process may be preceded by patterning a hardmask 132, e.g., with silicon oxide (SiO₂), silicon nitride (Si₃N₄) and silicon oxide (SiO₂) layers. In any event, in contrast to conventional processes, monocrystalline SiGe base profile layer 130 is substantially uniform in thickness and substantially continuous, even over implanted porous silicon region 120. In addition, monocrystalline SiGe base profile layer 130 is monocrystalline SiGe over implanted porous silicon region 120, which will eventually be converted to an isolation region 106 (FIG. 11). Monocrystalline SiGe base profile layer 130 may be formed using any now known or later developed technique, e.g., deposition, epitaxial growth, etc.

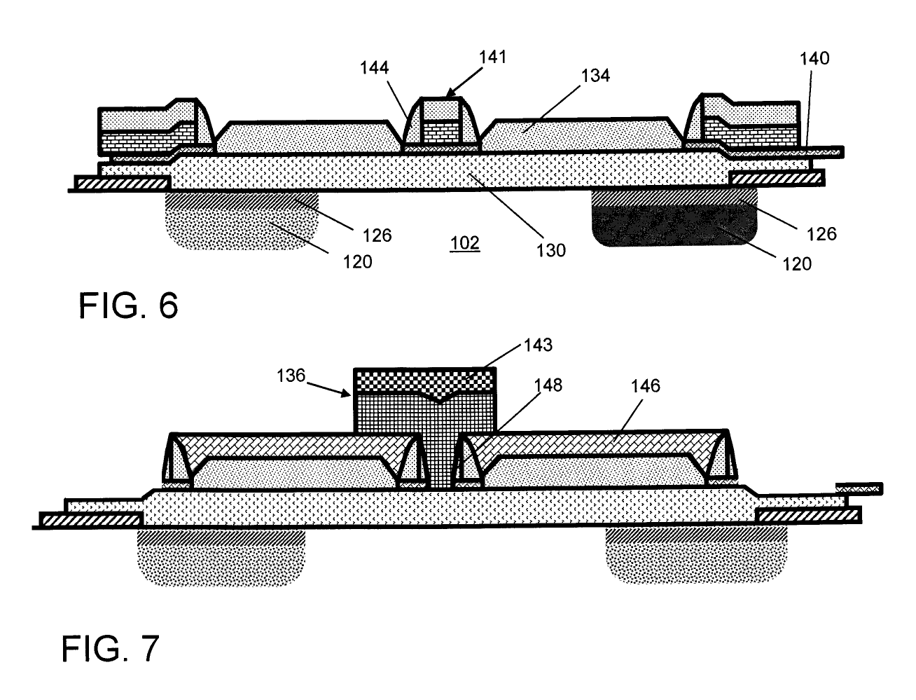

FIGS. 6-7 show forming a monocrystalline silicon extrinsic base 134 (FIG. 6) and a polysilicon emitter 136 (FIG. 7) over monocrystalline SiGe base profile layer 130, via a dummy emitter 141. These processes may include any now known or later developed techniques. For example, a thin silicon oxide (SiO₂) stopping layer 140 may be deposited, followed by dummy emitter 141 deposition and patterning. After nitride spacer 144 deposition and etch, silicon oxide stopping layer 140 is removed. Next, as shown in FIG. 6, extrinsic base 134 may be formed. In contrast to conventional processing, however, an area in which monocrystalline extrinsic base 134 is to be formed includes monocrystalline silicon germanium base profile layer 130. As a result, extrinsic base 134 may be formed, for example, by epitaxially growing monocrystalline silicon on monocrystalline SiGe base profile layer 130. Monocrystalline extrinsic base 134 may be either grown non-selectively (not shown) or selectively, as shown. The non-selective process may be followed by polishing, i.e., chemical mechanical polishing (CMP), and recessing. The selective process requires no further CMP or recessing to achieve the structure in FIG. 6.

FIG. 7 shows the structure after further processing to form polysilicon emitter 136. These processes may include any now known or later developed techniques. For example, depositing an isolation oxide 146 and planarizing by polishing and etch-back, and removing dummy emitter 141 (FIG. 6). After an inner nitride spacer 148 formation, stopping oxide layer 140 (FIG. 6) is removed in the emitter region and (e.g., an n-type, phosphorous doped polysilicon) polysilicon emitter 136 is deposited either selectively (not shown) or non-selectively, patterned with resist 143, and etched (e.g., a reactive ion etch (RIE)). Polysilicon emitter 136 is substantially T-shaped.

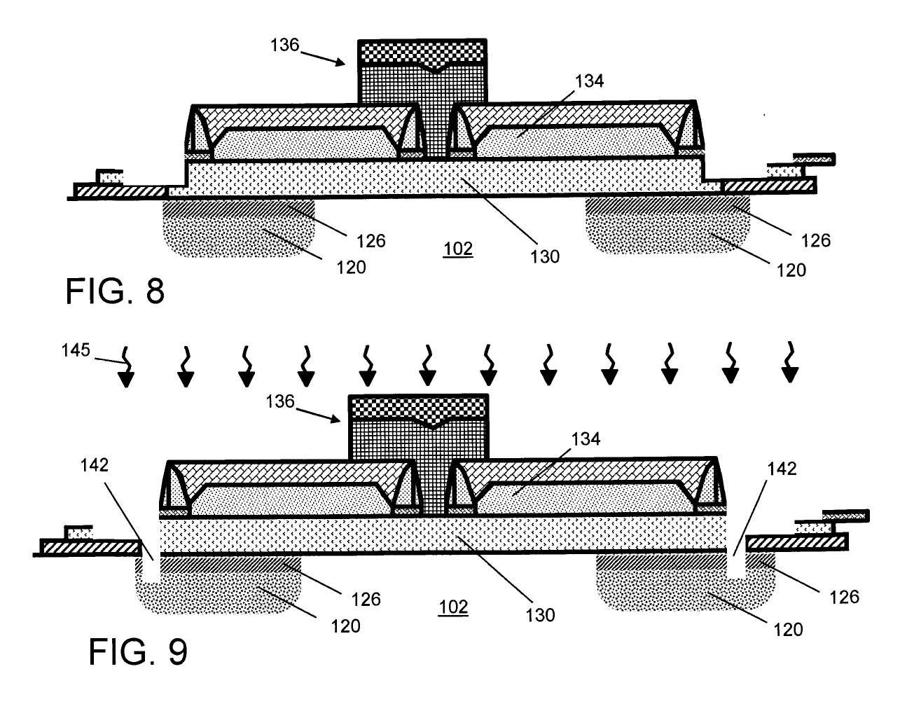

As shown in FIGS. 8-9, before salicidation and other back-end-of-line processing, an opening 142 (FIG. 9) is formed through on an outer perimeter, e.g., by timed RIE. The depth of opening 142 is relatively non-critical so long as it reaches implanted porous silicon region 120. In one embodiment, polysilicon emitter 136 etch can be extended to reach underlying implanted porous silicon region 120, i.e., at least monocrystalline silicon film 126.

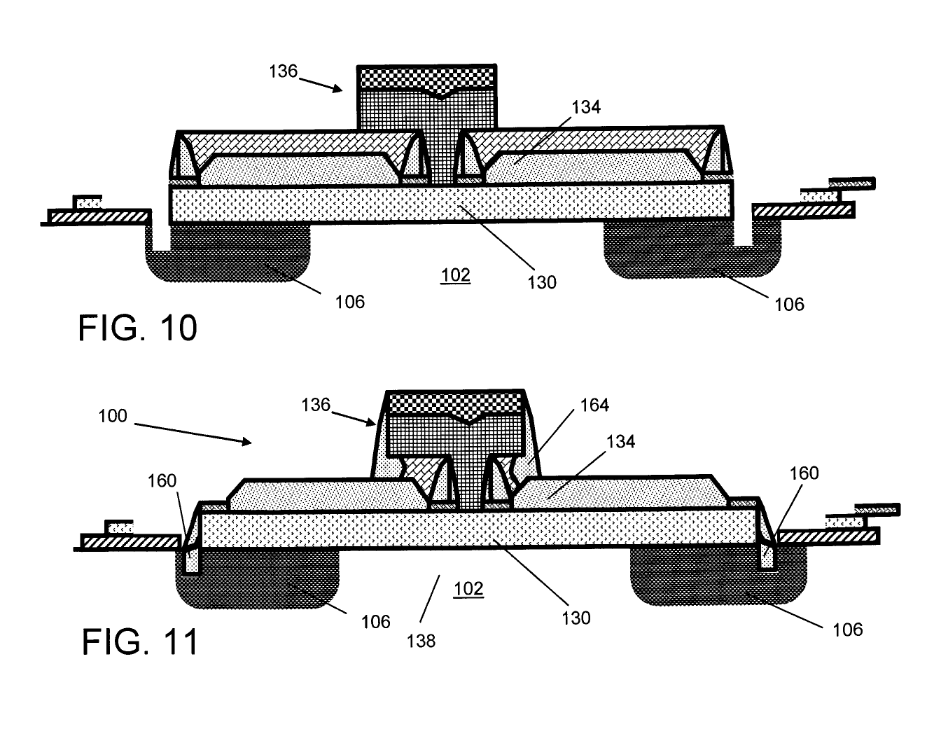

FIGS. 9-14 show various embodiments of converting implanted porous silicon region 120 (FIG. 9) to an isolation region 106 (FIGS. 10-11, 13, 14). In each embodiment, an opening 142 is formed, e.g., via reactive ion etching, to implanted porous silicon region 120 (FIG. 9). In a first embodiment, shown in FIGS. 9-11, a low temperature oxidation (LTO) 145 (e.g., at approximately 400° C.) of implanted porous silicon region 120 is performed to convert implanted porous silicon region 120 to a dielectric, i.e., silicon oxide (SiO₂). FIG. 10 shows isolation region 106 after oxidation 145 (FIG. 9). FIG. 11 shows HBT 100 after subsequent processing including capping of isolation region 106, e.g., with a silicon nitride (Si₃N₄) plug 160. Other processing may include, for example, oxide etching to remove oxide layer 146, a nitride etch and nitride spacer 164 formation.

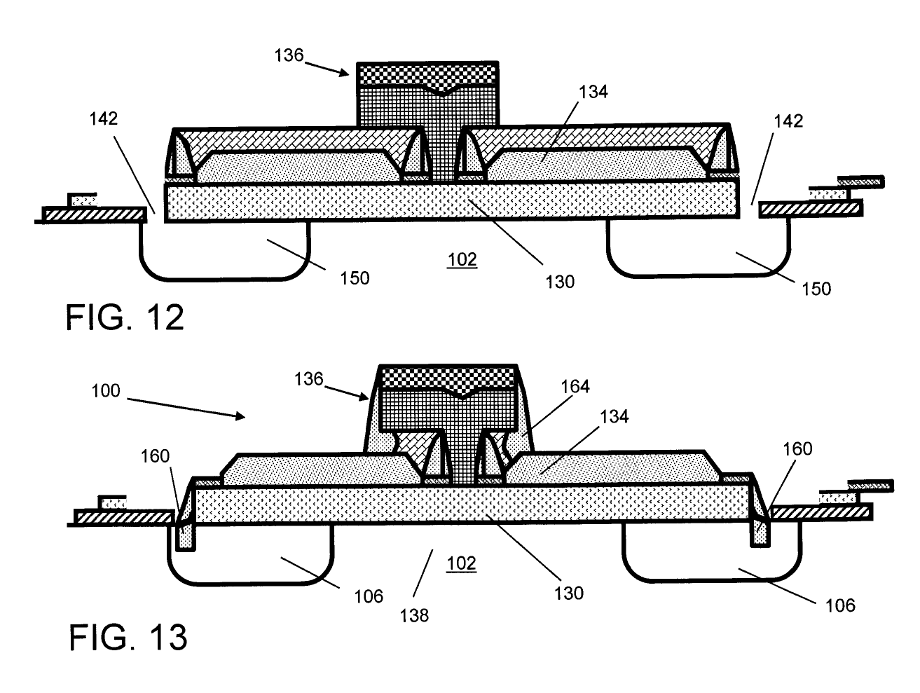

FIGS. 12-13 show a second embodiment of converting implanted porous silicon region 120 (FIG. 9) to isolation region 106 (FIG. 13). In this case, implanted porous silicon region 120 (FIG. 9) is removed via opening 142, e.g., by a collapsing etch to form void 150, and opening 142 is sealed to form isolation region 106 (FIG. 13) as a gas. As shown in FIG. 13, a silicon nitride (Si₃N₄) plug 160 may be used to seal isolation region 106.

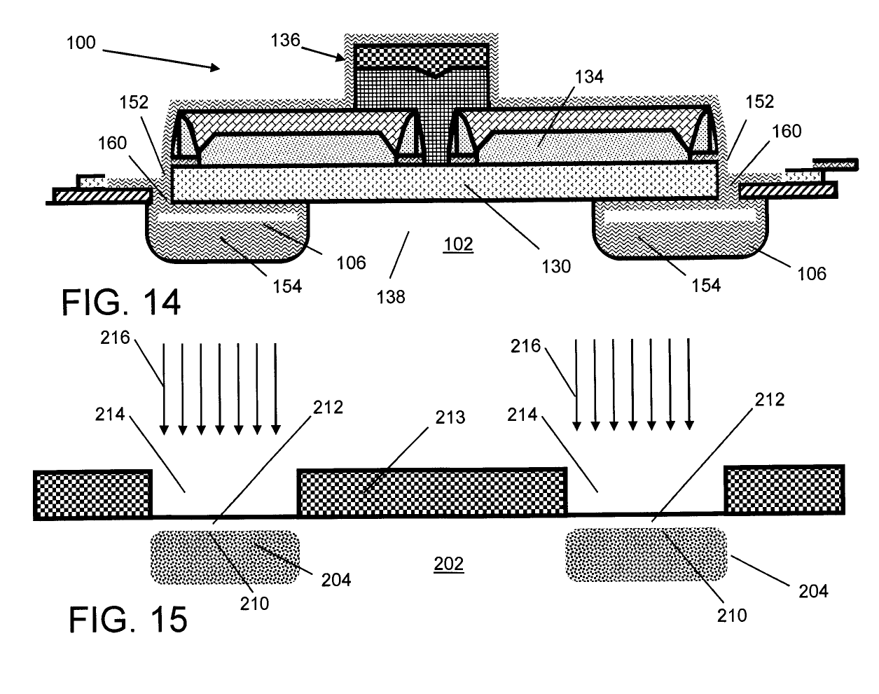

FIGS. 12 and 14 show a third embodiment of converting implanted porous silicon region 120 (FIG. 9) to isolation region 106. In this embodiment, implanted porous silicon region 120 (FIG. 9) is removed via opening 142, e.g., by a collapsing etch, as shown in FIG. 12, to form void 150. In this case, however, void 150 is passivated, e.g., by deposition of a dielectric 152 (e.g., silicon oxide (SiO₂)) in void 150, and at least a portion of void 150 is re-filled with a dielectric 154 (e.g., silicon oxide (SiO₂)). As shown in FIG. 14, a plug 160 may be used to seal isolation region 106. Plug 160 may be made from passivation dielectric 152 or other dielectric material such as silicon nitride (Si₃N₄) .

In the above-described embodiments of FIGS. 12-14, undesired electrical effects of the remainder of the porous material on the sidewall of collector 138 (FIG. 14) (such as charge trapping, carrier scattering, increased recombination etc.) can be mitigated by a brief and shallow isotropic bulk silicon (Si) etch. Any remaining processing (i.e., back end of the line) proceeds as now known or later developed to finalize HBT 100 (FIGS. 11, 13, 14).

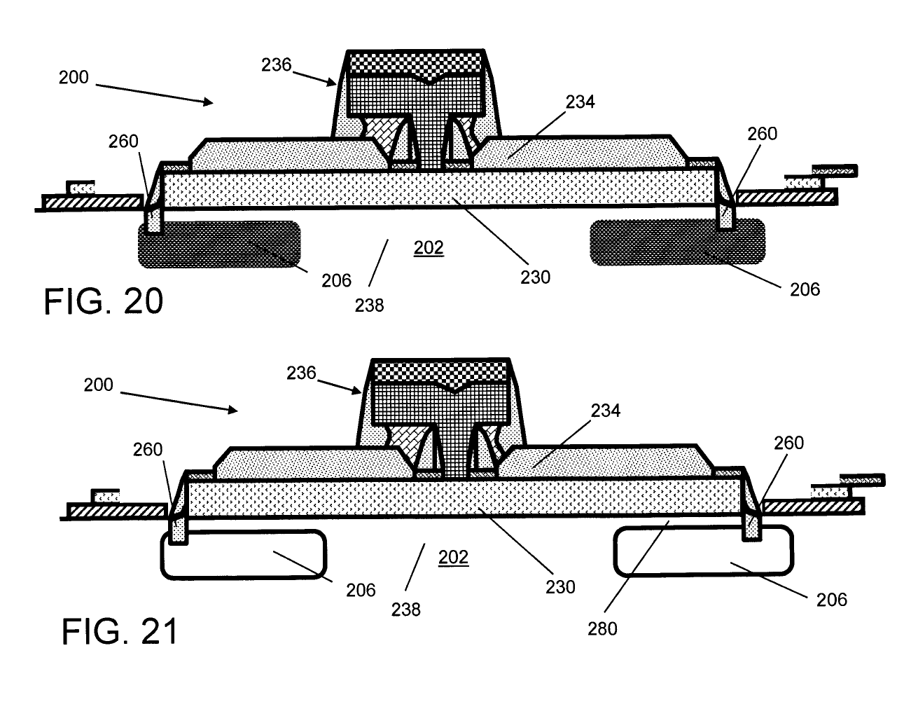

FIGS. 15-23 show a second embodiment of the method. In this case, a substrate 202 is provided, and an implanted region 204 is formed by ion implanting (e.g., boron (B)) at a location to be isolation region 206 (FIGS. 20-22) such that an upper surface 210 of implanted region 204 is distanced from a surface 212 of substrate 202. Surface 212 is capable of having monocrystalline silicon formed thereon. In this case, implanted region 204 includes the monocrystalline silicon (not doped) of substrate 202. Implanted region 204 may be formed, for example, by forming a mask 213 and patterning/etching to form an opening 214 therein, and then ion implanting 216. The dopant implanted may include any p-type silicon dopant, for example, boron (B).

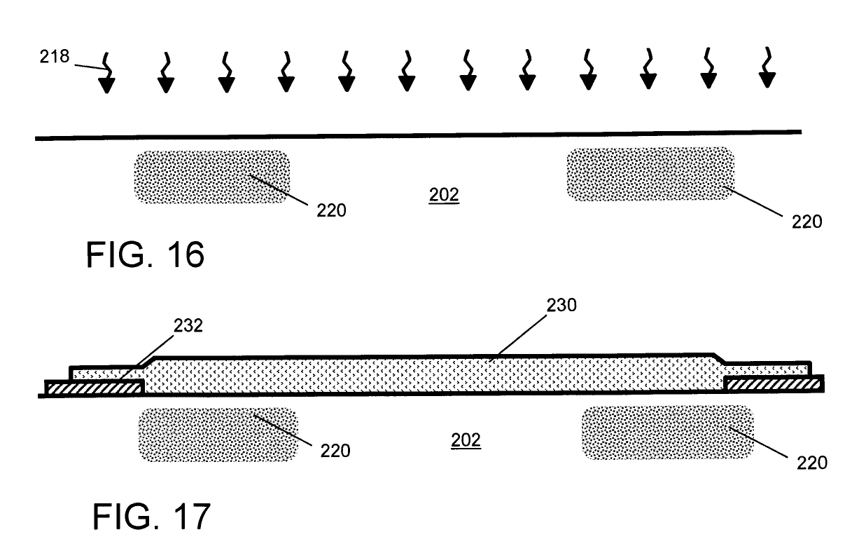

FIG. 16 shows removing mask 213 (FIG. 15) and performing an anodic porousification 218 on implanted region 204 (FIG. 15) to create implanted porous silicon regions 220. The mask removal may include any conventional resist stripping technique, e.g., wet etching. Anodic porousification 218 may include performing a hydrofluoric acid bath using a current density between 20-100 mA/cm². Porosification may be performed in darkness, or under illumination. In this case, anodic porousification 218 porosifies surface 212 (FIG. 15) but not to the extent of implanted region 104 (FIG. 15).

FIG. 17 shows forming a monocrystalline silicon germanium (SiGe) base profile layer 230 over implanted porous silicon region 220 and substrate 202. This process may be preceded by patterning a hardmask 232, e.g., with silicon oxide (SiO₂), silicon nitride (Si₃N₄), silicon oxide (SiO₂) layers. In any event, in contrast to conventional processes, monocrystalline SiGe base profile layer 230 is substantially uniform in thickness and substantially continuous, even over implanted porous silicon region 220. In addition, monocrystalline SiGe base profile layer 230 is monocrystalline SiGe over implanted porous silicon region 220, which will eventually be converted to an isolation region 206 (FIGS. 19-22).

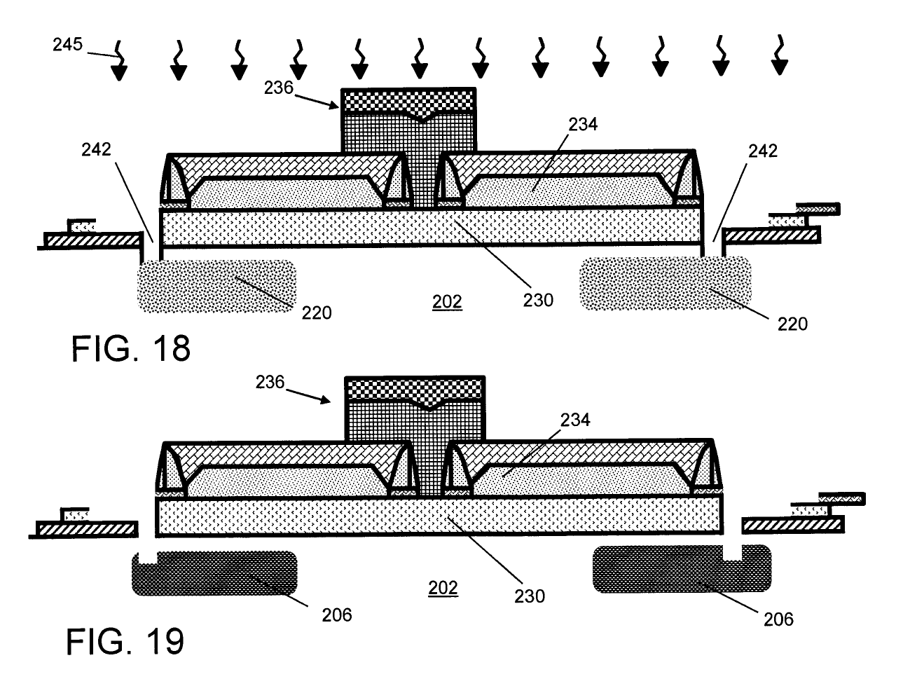

As shown in FIGS. 18-20, subsequent to this stage, processing may proceed as described herein relative to FIGS. 6-14. That is, as shown in FIG. 18, a monocrystalline extrinsic base 234 and a polysilicon emitter 236 are formed over monocrystalline SiGe base profile layer 230, via a dummy emitter (not shown-see FIG. 6). In contrast to FIGS. 6-14, however, implanted porous silicon region 220 being buried eliminates the need for a high-temperature skin formation (as in FIG. 3) after porousification 218, while maintaining chemical and structural stability for further processing. In addition, the omission of the high-temperature skin formation reduces the thermal budget of the integration process and helps maintain the porosity for selective removal or oxidation, as described herein.

As shown in FIG. 18, an opening 242 is formed, e.g., via reactive ion etching, to implanted porous silicon region 220 (FIG. 18) after/with formation of polysilicon emitter 236, which is substantially T-shaped. Subsequently, implanted porous silicon region 220 can be converted to an isolation region 206 (FIG. 19) using any of the embodiments described herein. FIGS. 18-19 show, for example, performing a low temperature oxidation 245 of implanted porous silicon region 220 to convert implanted porous silicon region 220 to a dielectric. FIG. 19 shows isolation region 206 after oxidation 245 (FIG. 18). FIG. 20 shows an HBT 200 after subsequent processing including capping of isolation region 206, e.g., with a silicon nitride (Si₃N₄) plug 260.

FIG. 21 shows an HBT 200 after implanted porous silicon region 220 conversion using the process of FIGS. 12-13. In this case, implanted porous silicon region 220 (FIG. 18) is removed via opening 242 (FIG. 18), e.g., by a collapsing etch to form a void, and opening 242 is sealed to form isolation region 206 (FIG. 21) as a gas dielectric. As shown in FIG. 21, a silicon nitride (Si₃N₄) plug 260 may be used to seal isolation region 206.

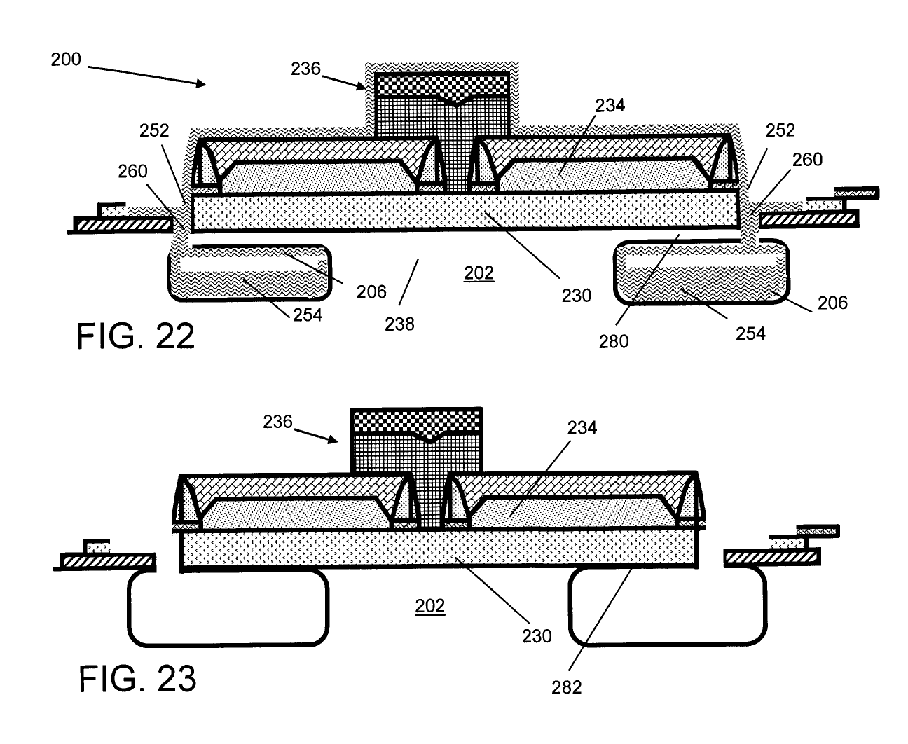

FIG. 22 shows an HBT 200 after implanted porous silicon region 220 conversion using the process of FIGS. 12 and 14. In this case, a void is passivated, e.g., by depositon of a dielectric 252 (e.g., silicon oxide (SiO₂)) in the void, and at least a portion of the void is re-filled with a dielectric 254 (e.g., silicon oxide (SiO₂)). As shown in FIG. 22, a plug 260 of passivation dielectric 252 or other dielectric material such as silicon nitride (Si₃N₄) may be used to seal isolation region 206.

In the above-described embodiments of FIGS. 21-22, undesired electrical effects of the remainder of the porous material on the sidewall of collector 238 (such as charge trapping, carrier scattering, increased recombination etc.) can be mitigated by a brief and shallow isotropic bulk silicon (Si) etch. Furthermore, in one alternative embodiment, shown in FIG. 23, prior to sealing isolation region 206 as in FIG. 21 or passivating/refilling as in FIG. 22, a portion 280 (FIGS. 21-22) of substrate 202 above implanted porous silicon region 220 may be removed, e.g., by a shallow isotropic silicon etch, to a lower surface 282 (FIG. 23) of monocrystalline silicon germanium base profile layer 230. Processing may then proceed as described relative to FIG. 21 or 22. Any remaining processing (i.e., back end of the line) occurs as now known or later developed to finalize HBT 200 (FIGS. 20-22).

As shown in FIGS. 11, 13, 14 and 20-22, the above-described methods result in a heterostructure bipolar transistor (HBT) 100, 200 including: substrate 102, 202, a polysilicon emitter 136, 236, a collector 138, 238, at least one isolation region 106, 206 adjacent to collector 138, 238, an intrinsic base 130, 230 (i.e., monocrystalline base profile layer) including monocrystalline silicon germanium extending over each isolation region 106, 206, and a monocrystalline silicon extrinsic base 134, 234. Each isolation region 106, 206 may include a plug 160, 260, sealing isolation region 106, 206 from an above layer. In some embodiments (FIGS. 13 and 21), isolation region 106, 206 includes a gas dielectric.

HBT 100, 200 exhibit a number of advantages. For example, HBT 100, 200 exhibit reduced collector-base capacitance (C_{cb}) and base resistance (R_{b}). In particular, employing sacrificial implanted porous silicon region 120, 220 enables the subsequent highly-selective removal from under the built device, greatly reducing the capacitance between the base and collector. In addition, the methodology described herein allows for a self-aligned extrinsic base 136, 236 deposition facilitating the integration process, and minimizing parasitic capacitances. The monocrystalline intrinsic base also allows for the selective deposition of the monocrystalline extrinsic base. This eliminates the need for CMP and RIE recess in the integration scheme. The mobility of monocrystalline silicon is inherently larger than that of equally doped polysilicon or amorphous material. Hence, a monocrystalline intrinsic base 130, 230 has a lower resistance. Since monocrystalline SiGe base profile layer 130, 230 forms as a continuous layer, by definition of epitaxy, a better link and bulk resistance can be achieved, compared to a discontinuous layer of conventional processes. The germanium (Ge) in the monocrystalline SiGe base profile layer 130, 230 causes biaxial strain that further increases lateral hole mobility and helps lower the base resistance.

The method and structure as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The foregoing description of various aspects of the invention has been presented for purposes of illustration and description. It is not intended to be exhaustive or to limit the invention to the precise form disclosed, and obviously, many modifications and variations are possible. Such modifications and variations that may be apparent to a person skilled in the art are intended to be included within the scope of the invention as defined by the accompanying claims.

What is claimed is:

1. A method of forming a heterostructure bipolar transistor (HBT), the method comprising:
providing a substrate;
forming an implanted region in the substrate;
forming a monocrystalline silicon germanium base profile layer over the implanted region and the substrate;
forming a dummy emitter on the monocrystalline silicon germanium base profile layer;
epitaxially growing a monocrystalline extrinsic base over the monocrystalline silicon germanium base profile layer;
converting the implanted region to an isolation region; and
replacing the dummy emitter with a polysilicon emitter.

2. The method of claim 1, wherein the monocrystalline silicon germanium base profile layer is substantially uniform in thickness and substantially continuous.

3. The method of claim 1, wherein the epitaxial growing is selective to the monocrystalline silicon germanium base profile layer.

4. The method of claim 1, wherein the epitaxial growing is non-selective to the monocrystalline silicon germanium base profile layer.

5. The method of claim 1, wherein the implanted region forming includes:
ion implanting to form the implanted region at a location to be the isolation region, wherein an upper surface of the implanted region is substantially co-planar with a surface of the substrate;
performing an anodic porousification on the implanted region; and
forming the upper surface into a monocrystalline silicon film by annealing.

6. The method of claim 5, wherein the converting includes forming an opening to the implanted region and one of the following:
a) performing a low temperature oxidation of the implanted region;
b) removing the implanted region, and sealing the opening to form a gas dielectric; and
c) removing the implanted region to form a void, passivating the void, and re-filling at least a portion of the void with a dielectric.

7. The method of claim 1, wherein the implanted region forming includes:
ion implanting to form the implanted region at a distance from a surface of the substrate; and
performing an anodic porousification on the implanted region.

8. The method of claim 7, wherein the converting includes forming an opening to the implanted region and one of the following:
a) performing a low temperature oxidation of the implanted region;
b) removing the implanted region, and sealing the opening to form a gas dielectric; and
c) removing the implanted region to form a void, passivating the void, and re-filling at least a portion of the void with a dielectric.

9. The method of claim 8, wherein the removing includes removing a portion of the substrate above the implanted region to a lower surface of the monocrystalline silicon germanium base profile layer.

10. The method of claim 1, wherein the converting includes forming an opening to the implanted region and one of the following:
a) performing a low temperature oxidation of the implanted region;
b) removing the implanted region, and sealing the opening to form a gas dielectric; and
c) removing the implanted region to form a void, passivating the void, and re-filling at least a portion of the void with a dielectric.

11. The method of claim 1, wherein the polysilicon emitter is substantially T-shaped.

12. A heterostructure bipolar transistor (HBT) comprising:
a substrate;
a polysilicon emitter atop the substrate;
a collector in the substrate;
at least one isolation region adjacent to the collector;
an intrinsic base including monocrystalline silicon germanium extending over each isolation region; and
a monocrystalline extrinsic base.

13. The HBT of claim 12, wherein each isolation region includes a plug sealing the isolation region from an above layer.

14. The HBT of claim 13, wherein the isolation region includes silicon oxide or a gas.

15. The HBT of claim 13, wherein the polysilicon emitter is substantially T-shaped.

16. A method comprising:
providing a substrate;
forming an implanted region in the substrate;
forming a monocrystalline silicon germanium layer over the implanted region and the substrate;
forming other structure over the monocrystalline silicon germanium layer; and
converting the implanted region to an isolation region.

17. The method of claim 16, wherein the monocrystalline silicon germanium layer is substantially uniform in thickness and substantially continuous.

18. The method of claim 16, wherein the implanted region forming includes:
ion implanting to form the implanted region at a location to be the isolation region, wherein an upper surface of the implanted region is substantially co-planar with a surface of the substrate;
performing an anodic porousification on the implanted region; and
forming the upper surface into a monocrystalline silicon film by annealing.

19. The method of claim 16, wherein the converting includes forming an opening to the implanted region and one of the following:
a) performing a low temperature oxidation of the implanted region;
b) removing the implanted region, and sealing the opening to form a gas dielectric; and
c) removing the implanted region to form a void, passivating the void, and re-filling at least a portion of the void with a dielectric.

20. The method of claim 16, wherein the implanted region forming includes:
ion implanting to form the implanted region at a distance from a surface of the substrate; and
performing an anodic porousification on the implanted region.
